(19) United States
(12) Patent Application Publication
(10) Pub. No.: US 2026/0135458 A1
(43) Pub. Date: May 14, 2026

(54) Current Sense Compensation Apparatus and Method

(71) Applicant: Reed Semiconductor Corporation, Warwick, RI (US)

(72) Inventors: Biranchinath Sahu, Bangalore (IN); Naga Venkata Prasadu Mangina, Karnataka (IN); Rajeev Singla, Mansa, Punjab (IN); Sushmit Mazumdar, Kolkata (IN)

(21) Appl. No.: 18/947,890

(22) Filed: Nov. 14, 2024

(51) Int. Cl. H02M 1/00; G01R 19/165; H02M 3/158

(52) U.S. Cl. CPC H02M 1/0009; G01R 19/16571; H02M 3/1584

(57) ABSTRACT

An apparatus includes a plurality of current sense resistors formed on a semiconductor die, wherein one current sense resistor of the plurality of current sense resistors is configured to receive a current signal proportional to a current flowing through a power conversion stage, and a current sense compensation circuit configured to counteract temperature-induced variations in the plurality of current sense resistors to achieve accurate current measurements across varying operating conditions.

### TECHNICAL FIELD

The present disclosure relates generally to the field of multiphase power conversion systems, and in particular embodiments, to techniques and mechanisms for accurately sensing currents within such systems by incorporating current sense resistors into a multiphase controller.

### BACKGROUND

As technologies further advance, a variety of processors such as Digital Signal Processors (DSPs), Field Programmable Gate Arrays (FPGAs), Central Processing Units (CPUs) and/or the like, have become popular. Each processor operates with a low supply voltage (e.g., sub-1V) and consumes a large amount of current. A multiphase power conversion system is employed to power the processor. The multiphase power conversion system comprises a multiphase controller and a plurality of power stages.

The multiphase controller is an integrated circuit designed to manage and regulate power delivery in the multiphase power conversion system. This type of controller is commonly used in power supplies for processors consuming a large amount of current. The multiphase controller is configured to control plurality of power stages by generating multiple Pulse Width Modulation (PWM) signals and monitoring current sense signals. The primary objective is to distribute the load across several phases, enhancing power delivery efficiency, reducing ripple, and improving overall performance.

The core of the multiphase controller is a PWM controller. In operation, the PWM controller generates precise PWM signals for each power stage. These signals are used to control the switching of MOSFETs in each phase, regulating the voltage and current supplied to the load. The PWM signals are typically phase-shifted to interleave the switching of each power stage. This reduces the input and output ripple currents, thereby improving the overall efficiency and reducing the size of filtering components.

In the multiphase power conversion system, each phase includes a current sense apparatus to monitor the current flowing through the inductor of this phase. The current sense signals from the plurality of power stages provide feedback to the multiphase controller for load balancing and protection. By analyzing the current sense signals, the multiphase controller ensures that each phase shares the load evenly. This prevents any single phase from becoming overloaded and enhances the longevity and reliability of the power conversion system.

In the multiphase power conversion system, the average current plays a crucial role in various aspects of regulation and efficiency. It is used within the load and/or line regulation to adjust the output voltage dynamically based on the load current, thereby optimizing the performance and reducing voltage overshoot or droop during load transients. Additionally, the average current is a key parameter in the control loop, where it is monitored and fed back to ensure stable operation across the phases by adjusting the duty cycle or phase timing to maintain desired output conditions. The multiphase power conversion system also utilizes the average current to implement auto phase add/drop functionality, automatically engaging or disengaging phases as load conditions change. This helps to improve efficiency under light loads by reducing the number of active phases, while providing additional current capacity under heavier loads by activating more phases.

In the multiphase power conversion system, the per-phase sensed current is critical for implementing over-current protection (OCP). The current in each phase is monitored individually to detect any excessive current that may occur due to faults or transient conditions. By sensing the current in each phase, the multiphase power conversion system can compare it against a predetermined current threshold. If the current in any phase exceeds this threshold, the over-current protection mechanism is triggered, either reducing the duty cycle, shutting down the affected phase, or disabling the entire system to prevent damage to components and ensure system safety.

In the multiphase power conversion system, the per-phase sensed current is essential for implementing current telemetry, which provides real-time monitoring of the current flowing through each phase. By accurately sensing the current in each phase, the multiphase power conversion system is capable of reporting detailed information about the distribution of the load across the active phases. This current telemetry data is valuable for assessing the performance of the multiphase power conversion system, ensuring balanced current sharing between phases, and detecting anomalies like phase imbalance or phase loss.

In the multiphase power conversion system, as the number of phases increases, the number of current sense resistors on the board also increases, which results in several design challenges. Board area limitations become a concern since additional space is required to accommodate the extra current sense resistors. Furthermore, the bill of materials (BOM) cost rises due to the inclusion of more current sense resistors. This can also affect the reliability of the design, as more discrete components increase the chances of failure.

To address these issues, integrating current sense resistors into the semiconductor die wherein the multiphase controller is formed is a practical solution. However, in semiconductor processes, resistances are typically realized using a combination of positive and negative temperature coefficient poly resistors, which introduces temperature-induced variations. To mitigate these variations, numerous trim switches are required to precisely adjust and compensate for the temperature effects, ensuring accurate current sensing and stable operation across varying temperatures. The use of more trim switches in the multiphase controller introduces several challenges. First, it increases the overall complexity of the design, as additional circuitry is required to implement and manage the trim adjustments. This not only makes the design process more intricate but can also lead to higher chances of design errors or performance inconsistencies. Second, the inclusion of more trim switches adds extra cost, as each switch is an additional component that contributes to the overall expense of the system. Finally, more trim switches require additional layout space on the circuit board, which can be a significant concern in designs with tight space constraints. This can limit the ability to accommodate other critical components or necessitate a larger board size, increasing production costs and complexity. Thus, there is a need for a current sense compensation apparatus that precisely adjust and compensate for the temperature effects, ensuring accurate current sensing. The present disclosure addresses this requirement.

### SUMMARY

Technical advantages are generally achieved, by embodiments of this disclosure which describe a current sense compensation apparatus for accurately sensing currents in a multiphase power conversion system.

In accordance with one aspect of the present disclosure, an apparatus comprises a plurality of current sense resistors formed on a semiconductor die, wherein one current sense resistor of the plurality of current sense resistors is configured to receive a current signal proportional to a current flowing through a power conversion stage, and a current sense compensation circuit configured to counteract temperature-induced variations in the plurality of current sense resistors to achieve accurate current measurements across varying operating conditions.

In accordance with another aspect of the present disclosure, a method comprises configuring a plurality of current sources to generate a plurality of currents, each of the plurality of currents proportional to a current flowing through a corresponding power stage, configuring the plurality of currents to flow through respective current sense resistors to generate a plurality of current sense voltage signals, configuring a current averaging circuit to generate an average current signal based on the plurality of current sense voltage signals fed into the current averaging circuit, and configuring a current sense compensation circuit to counteract temperature-induced variations in the current sense resistors to achieve an accurate current measurement of the average current signal.

In accordance with another aspect of the present disclosure, a power conversion system comprises a plurality of power stages connected in parallel between an input voltage bus and an output voltage bus, and a controller comprising a plurality of current sense resistors and a current sense compensation circuit, wherein one current sense resistor of the plurality of current sense resistors is configured to receive a current signal proportional to a current flowing through a power stage, and a current sense compensation circuit is configured to counteract temperature-induced variations in the plurality of current sense resistors to achieve accurate current measurements across varying operating conditions.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a power conversion system in accordance with various embodiments of the present disclosure;

FIG. 2 illustrates a schematic diagram of the smart power stage shown in FIG. 1 in accordance with various embodiments of the present disclosure;

FIG. 3 illustrates a schematic diagram of the current sense circuit of the power conversion system shown in FIG. 1 in accordance with various embodiments of the present disclosure;

FIG. 4 illustrates a schematic diagram of a first implementation of the current sense compensation circuit in accordance with various embodiments of the present disclosure;

FIG. 5 illustrates a schematic diagram of a second implementation of the current sense compensation circuit in accordance with various embodiments of the present disclosure;

FIG. 6 illustrates a schematic diagram of a third implementation of the current sense compensation circuit in accordance with various embodiments of the present disclosure;

FIG. 7 illustrates a schematic diagram of a fourth implementation of the current sense compensation circuit in accordance with various embodiments of the present disclosure; and

FIG. 8 illustrates a flow chart of a method for accurate current sensing in the power conversion system shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely a current sense compensation apparatus for accurately sensing currents in a multiphase power conversion system. The disclosure may also be applied, however, to a variety of power conversions systems. Hereinafter, various embodiments will be explained in detail with reference to the accompanying drawings.

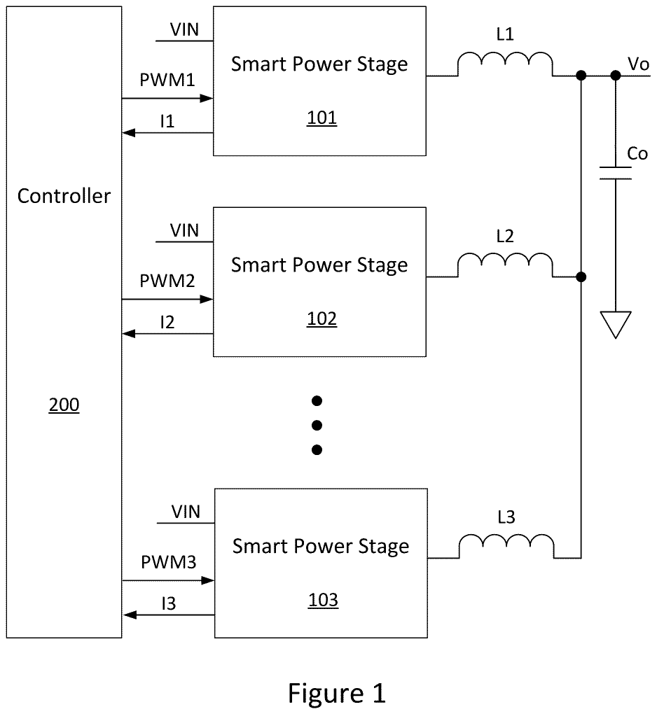

FIG. 1 illustrates a block diagram of a power conversion system in accordance with various embodiments of the present disclosure. The power conversion system comprises a multiphase controller 200, a plurality of smart power stages 101, 102 and 103, a plurality of inductors L1, L2 and L3, and an output capacitor Co. As shown in FIG. 1, each of the plurality of smart power stages (e.g., smart power stage 101) and a corresponding inductor (e.g., L1) are connected in series to form a power conversion stage. In some embodiments, the power conversion stage is a step-down power conversion stage. The plurality of smart power stages 101, 102 and 103, and the plurality of inductors L1, L2 and L3 form a plurality of step-down power conversion stages connected in parallel between an input voltage bus VIN and an output voltage bus Vo. A load (not shown) is coupled to the output voltage bus Vo. In some embodiments, the load may be a processor (e.g., a central processing unit).

The multiphase controller 200 is connected to the plurality of smart power stages 101, 102 and 103. The multiphase controller 200 feeds a PWM signal PWM1 to a first smart power stage 101. The multiphase controller 100 feeds a PWM signal PWM2 to a second smart power stage 102. The multiphase controller 100 feeds a PWM signal PWM3 to a third smart power stage 103. As shown in FIG. 1, the multiphase controller 200 receives a first current sense signal I1 from the first smart power stage 101. The multiphase controller 200 receives a second current sense signal I2 from the second smart power stage 102. The multiphase controller 200 receives a third current sense signal I3 from the third smart power stage 103.

The multiphase controller 200 acts as a central control unit that coordinate the operation of all smart power stages. The multiphase controller 200 generates PWM signals, which are essential for controlling the output voltage and current of each smart power stage. The PWM signals are precisely timed and modulated to manage power delivery efficiently. The multiphase controller 200 receives current sense signals from smart power stages. These current sense signals provide feedback about the current being delivered by each phase, allowing the multiphase controller 200 to monitor and adjust the operation of the smart power stages.

Each smart power stage represents an individual phase of the multiphase power conversion system. They are independently controlled by the PWM signals sent from the multiphase controller 200. Each smart power stage includes current sensing mechanisms to measure the current flowing through it. The sensed current data is then sent back to the multiphase controller 200. The current sense signals are used by the multiphase controller 200 to adjust the PWM signals dynamically, ensuring power delivery and load balancing across all phases.

In operation, the multiphase controller 200 calculates the required PWM signals based on the desired output and the feedback received from the smart power stages. The multiphase controller 200 sends out these PWM signals to the respective smart power stages, controlling their operation in a synchronized manner. Each smart power stage senses the current flowing through it and sends this data back to the multiphase controller 200. The multiphase controller 200 processes this current sense information to determine the load distribution and current levels in each phase. Based on the feedback, the multiphase controller 200 dynamically adjusts the PWM signals fed into the smart power stages. This adjustment helps in balancing the load, preventing any single phase from becoming overloaded, and maintaining the overall efficiency and stability of the multiphase power conversion system.

In some embodiments, the multiphase controller 200 may be a system controller or a system control apparatus. The multiphase controller 200 may be implemented as a microprocessor, a digital signal processor and the like.

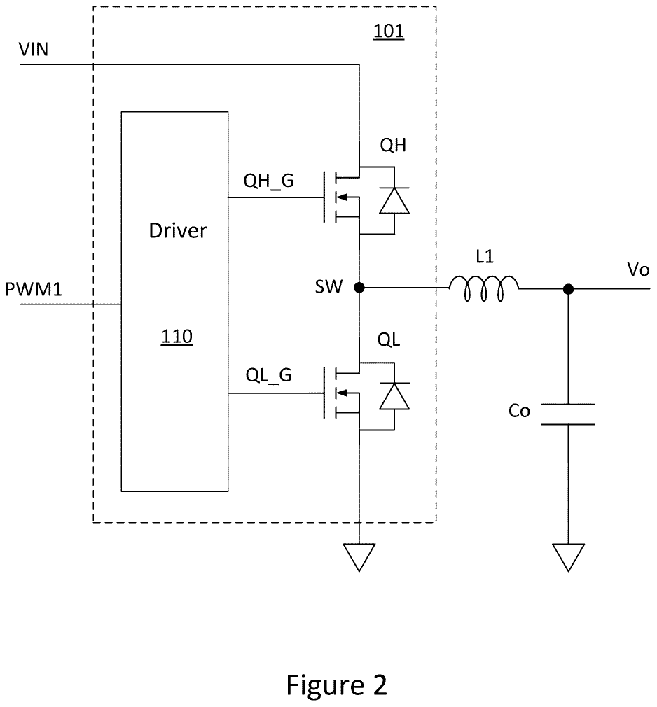

In some embodiments, the power conversion stage (e.g., power conversion stage formed by the smart power stage 101 and the inductor L1) is implemented as a step-down power converter. In some embodiments, the smart power stage comprises both high-side and low-side power switches responsible for regulating the output voltage of the step-down power converter. The smart power stage also includes the gate driver circuitry that controls the high-side and low-side power switches, optimizing the switching operation for speed and efficiency. The smart power stage may further comprise other key components such as current sensing, temperature sensing, overcurrent protection, overvoltage protection, under-voltage protection and various digital communication interfaces. The detailed structure of the smart power stage will be described below with respect to FIG. 2. Alternatively, the power conversion stage may be implemented as any suitable power converters such as an inductor-inductor-capacitor (LLC) converter, a switched capacitor converter, a hybrid switched capacitor converter, a full bridge power converter, a half bridge power converter, a buck converter, any combinations thereof and the like.

It should be noted that FIG. 1 illustrates only three smart power stages of a multiphase power conversion system that may include a plurality of such smart power stages. The number of smart power stages illustrated herein is limited solely for the purpose of clearly illustrating the inventive aspects of the various embodiments. The present disclosure is not limited to any specific number of smart power stages.

FIG. 2 illustrates a schematic diagram of the smart power stage shown in FIG. 1 in accordance with various embodiments of the present disclosure. The smart power stage 101 comprises a high-side switch QH, a low-side switch QL and a driver 110. As shown in FIG. 2, the high-side switch QH and the low-side switch QL are connected in series between the input voltage bus VIN and ground. An output inductor L1 is connected between a common node (SW) of the high-side switch QH and the low-side switch QL, and the output voltage bus Vo. The output capacitor Co is connected between the output voltage bus Vo and ground. The driver 110 is configured to receive a PWM signal PWM1 from the multiphase controller 200. Based on the received signal, the driver 110 generates gate drive signals QH_G and QL_G for the high-side switch QH and the low-side switch QL, respectively. In some embodiments, the high-side switch QH, the low-side switch QL and the driver 110 are in a smart power stage semiconductor package.

In operation, when the high-side switch QH is turned on, and the low-side switch QL is turned off, a current flows from the input voltage VIN to the load through the output inductor L1. The output inductor L1 opposes sudden changes in current by storing energy in its magnetic field. The output capacitor Co supplies the load with current, smoothing out the output voltage Vo. When the high-side switch QH is turned off, and the low-side switch QL is turned on, the output inductor L1 releases its stored energy to maintain the current flow to the load. The output capacitor Co continues to smooth the output voltage. In operation, the duty cycle (the ratio of the turn-on time of the high-side switch QH to the total switching period) is used to control the output voltage Vo. By adjusting the duty cycle, the output voltage Vo can be regulated at a predetermined level.

In accordance with an embodiment, the switches (e.g., switches QH and QL) may be metal oxide semiconductor field-effect transistor (MOSFET) devices. Alternatively, the switches can be any controllable switches such as insulated gate bipolar transistor (IGBT) devices, integrated gate commutated thyristor (IGCT) devices, gate turn-off thyristor (GTO) devices, silicon controlled rectifier (SCR) devices, junction gate field-effect transistor (JFET) devices, MOS controlled thyristor (MCT) devices, gallium nitride (GaN)-based power devices, silicon carbide (SiC)-based power devices and the like.

It should be noted while FIG. 2 shows the switches QH and QL are implemented as single n-type transistors, a person skilled in the art would recognize there may be many variations, modifications and alternatives. For example, depending on different applications and design needs, the switches QH and QL may be implemented as p-type transistors. Furthermore, each switch shown in FIG. 2 may be implemented as a plurality of switches connected in parallel. Moreover, a capacitor may be connected in parallel with one switch to achieve zero voltage switching (ZVS)/zero current switching (ZCS).

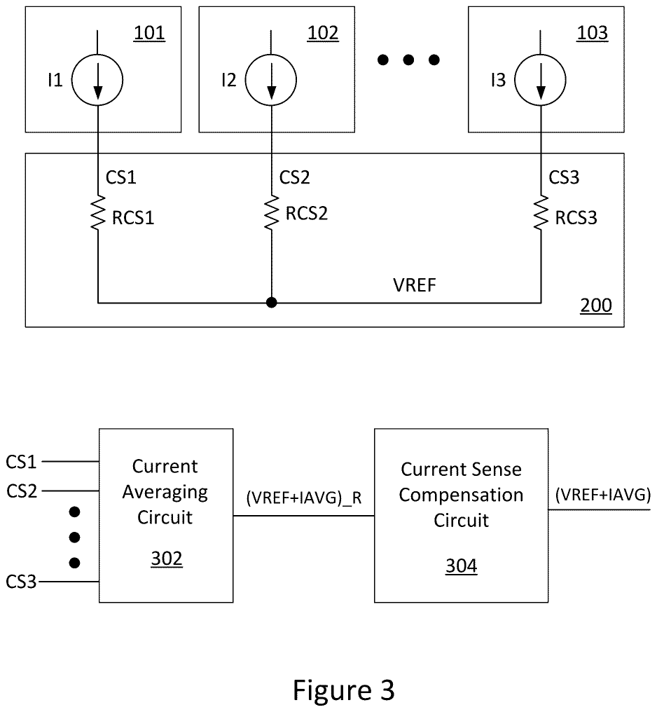

FIG. 3 illustrates a schematic diagram of the current sense circuit of the power conversion system shown in FIG. 1 in accordance with various embodiments of the present disclosure. Each smart power stage includes a current sense circuit. The current sense circuit is configured to generate a sensed current proportional to the current flowing through the smart power stage. In some embodiments, the sensed current is proportional to the current flowing through the high-side switch of the smart power stage. In alternative embodiments, the sensed current is proportional to the current flowing through the low-side switch of the smart power stage. Furthermore, depending on design needs, the sensed current is proportional to a combination of the current flowing through the high-side switch and the current flowing through the low-side switch of the smart power stage. As shown in FIG. 3, a first current source I1 represents the sensed current from the first smart power stage 101. A second current source I2 represents the sensed current from the second smart power stage 102. A third current source I3 represents the sensed current from the third smart power stage 103.

In order to solve the board area limitations in the multiphase power conversion system, a plurality of current resistors RCS1, RCS2 and RCS3 is integrated into the semiconductor die where the multiphase controller 200 is formed. As shown in FIG. 3, a first current sense resistor RCS1 is connected between the first current source I1 and a reference voltage VREF. The first current source I1 is configured to produce a first current signal proportional to a current flowing through the first smart power stage 101. The voltage on the node CS1 is equal to a sum of the reference voltage VREF and I1×RCS1. A second current sense resistor RSC2 is connected between the second current source I2 and the reference voltage VREF. The second current source I2 is configured to produce a second current signal proportional to a current flowing through a second smart power stage 102. The voltage on the node CS2 is equal to a sum of the reference voltage VREF and I2×RCS2. A third current sense resistor RSC3 is connected between the third current source I3 and the reference voltage VREF. The third current source I3 is configured to produce a second current signal proportional to a current flowing through the third smart power stage 103. The voltage on the node CS3 is equal to a sum of the reference voltage VREF and I3×RCS3.

In some embodiments, the resistance value of RCS1 is in a range from about 500 ohms to about 1000 ohms. The resistance value of RCS2 is in a range from about 500 ohms to about 1000 ohms. The resistance value of RCS3 is in a range from about 500 ohms to about 1000 ohms.

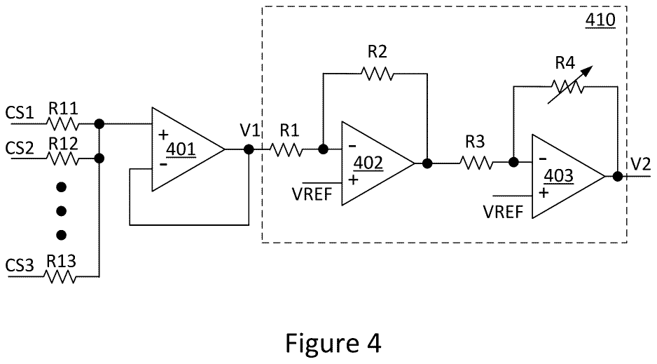

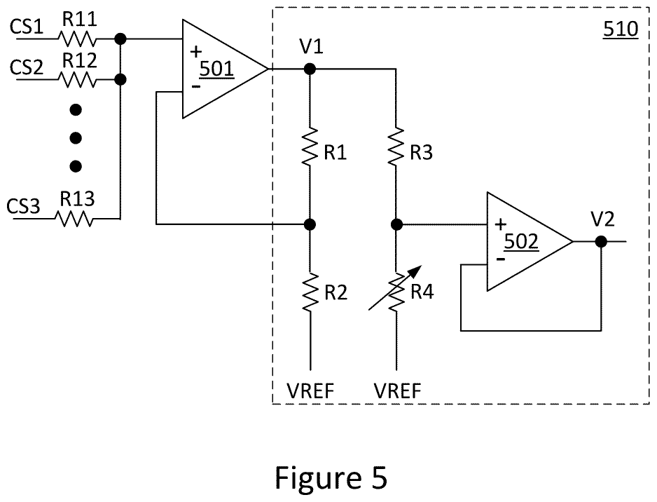

The sensed currents of all phases are fed into a current averaging circuit 302. The current averaging circuit 302 is configured to generate an average current signal. This average current signal is equal to a sum of the reference voltage and an average of the sensed currents. The average current signal is denoted as (VREF+IAVG)_R as shown in FIG. 3. The detailed structure and operating principle of the current averaging circuit 302 will be described below with respect to FIGS. 4-5.

As shown in FIG. 3, the current sense resistors RCS1, RCS2 and RCS3 are integrated into the semiconductor die wherein the multiphase controller 200 is formed. In semiconductor processes, resistances are typically realized using a combination of positive and negative temperature coefficient poly resistors, which introduces temperature-induced variations. To mitigate these variations, a current sense compensation circuit 304 is employed to precisely adjust and compensate for the temperature effects, ensuring accurate current sensing and stable operation across varying temperatures. The output of the current sense compensation circuit 304 is the compensated average current signal. The compensated average current signal is denoted as (VREF+IAVG) as shown in FIG. 3. The detailed structure and operating principle of the current sense compensation circuit 304 will be described below with respect to FIGS. 4-5.

FIG. 4 illustrates a schematic diagram of a first implementation of the current sense compensation circuit in accordance with various embodiments of the present disclosure. In the multiphase controller 200, the current sense signals CS1, CS2, CS3 are fed into an amplifier 401. The amplifier 401 functions as the current averaging circuit configured to generate an average current signal V1. The current sense compensation circuit 410 is employed to adjust the average current signal V1 so that the output of the current sense compensation circuit 410 is precisely adjusted and compensated for the temperature effects, ensuring accurate current sensing.

As shown in FIG. 4, the non-inverting input of the amplifier 401 is connected to a common node (CS1) of the first current source I1 and the first current sense resistor RSC1 through a first resistor R11. The non-inverting input of the amplifier 401 is connected to a common node (CS2) of the second current source I2 and the second current sense resistor RSC2 through a second resistor R12. The non-inverting input of the amplifier 401 is connected to a common node (CS3) of the third current source I3 and the third current sense resistor RSC3 through a third resistor R13. The output of the amplifier 401 is connected to the inverting input of the amplifier 401. In operation, the output of the amplifier 401 is configured to generate a voltage signal equal to a sum of the voltage reference VREF and an average current signal.

The current sense compensation circuit 410 comprises a first current sense compensation amplifier 402, a second current sense compensation amplifier 403, a first current sense compensation resistor R1, a second current sense compensation resistor R2, a third current sense compensation resistor R3 and a fourth current sense compensation resistor R4. As shown in FIG. 4, an inverting input of the first current sense compensation amplifier 402 is connected to the output of the amplifier 401 through the first current sense compensation resistor R1. A non-inverting input of the first current sense compensation amplifier 402 is connected to a predetermined reference VREF. The second current sense compensation resistor R2 is connected between the inverting input and an output of the first current sense compensation amplifier 402. An inverting input of the second current sense compensation amplifier 403 is connected to the output of the first current sense compensation amplifier 402 through the third current sense compensation resistor R3. A non-inverting input of the second current sense compensation amplifier 403 is connected to the predetermined reference VREF. The fourth current sense compensation resistor R4 is connected between the inverting input and an output of the second current sense compensation amplifier 403.

As indicated by the arrow placed on top of R4, the fourth current sense compensation resistor R4 is an adjustable resistor. In operation, a resistance of the fourth current sense compensation resistor R4 is dynamically adjusted to achieve the accurate current measurements across the varying operating conditions. More particularly, when the resistance values of RCS1, RCS2 and RCS3 in the multiphase controller 200 are higher than the nominal value (e.g., 1000 ohms), the fourth current sense compensation resistor R4 is trimmed down from its nominal value. When the resistance values of RCS1, RCS2 and RCS3 in the multiphase controller 200 are lower than the nominal value (e.g., 1000 ohms), the fourth current sense compensation resistor R4 is trimmed up from its nominal value. By appropriately choosing the values of R1, R2, R3, R4 and trimming R4, the semiconductor process variation can be compensated.

FIG. 5 illustrates a schematic diagram of a second implementation of the current sense compensation circuit in accordance with various embodiments of the present disclosure. In the multiphase controller 200, the current sense signals CS1, CS2, CS3 are fed into an amplifier 501. The amplifier 501 is configured to generate an average current signal V1. The current sense compensation circuit 510 is employed to adjust the average current signal V1 so that the output of the current sense compensation circuit 510 is precisely adjusted and compensated for the temperature effects, ensuring accurate current sensing.

As shown in FIG. 5, the non-inverting input of the amplifier 501 is connected to a common node (CS1) of the first current source I1 and the first current sense resistor RSC1 through a first resistor R11. The non-inverting input of the amplifier 501 is connected to a common node (CS2) of the second current source I2 and the second current sense resistor RSC2 through a second resistor R12. The non-inverting input of the amplifier 501 is connected to a common node (CS3) of the third current source I3 and the third current sense resistor RSC3 through a third resistor R13. The output of the amplifier 501 is connected to the inverting input of the amplifier 501 through the current sense compensation circuit 510. In operation, the output of the amplifier 501 is configured to generate a voltage signal equal to a sum of the voltage reference and an average current signal.

As shown in FIG. 5, the current sense compensation circuit 510 comprises a current sense compensation amplifier 502, a first current sense compensation resistor R1, a second current sense compensation resistor R2, a third current sense compensation resistor R3 and a fourth current sense compensation resistor R4. The first current sense compensation resistor R1 and the second current sense compensation resistor R2 are connected in series between the output of the amplifier 501 and a predetermined reference VREF. A common node of the first current sense compensation resistor R1 and the second current sense compensation resistor R2 is connected to the inverting input of the amplifier 501. The third current sense compensation resistor R3 and the fourth current sense compensation resistor R4 are connected in series between the output of the amplifier 501 and the predetermined reference VREF. A common node of the third current sense compensation resistor R3 and the fourth current sense compensation resistor R4 is connected to a non-inverting input of the current sense compensation amplifier 502. An output of the current sense compensation amplifier 502 is connected to an inverting input of the current sense compensation amplifier 502.

As indicated by the arrow placed on top of R4, the fourth current sense compensation resistor R4 is an adjustable resistor. In operation, a resistance of the fourth current sense compensation resistor R4 is dynamically adjusted to achieve the accurate current measurements across the varying operating conditions. More particularly, when the resistance values of RCS1, RCS2 and RCS3 in the multiphase controller 200 are higher than the nominal value (e.g., 1000 ohms), the fourth current sense compensation resistor R4 is trimmed down from its nominal value. When the resistance values of RCS1, RCS2 and RCS3 in the multiphase controller 200 are lower than the nominal value (e.g., 1000 ohms), the fourth current sense compensation resistor R4 is trimmed up from its nominal value. By appropriately choosing the values of R1, R2, R3, R4 and trimming R4, the semiconductor process variation can be compensated.

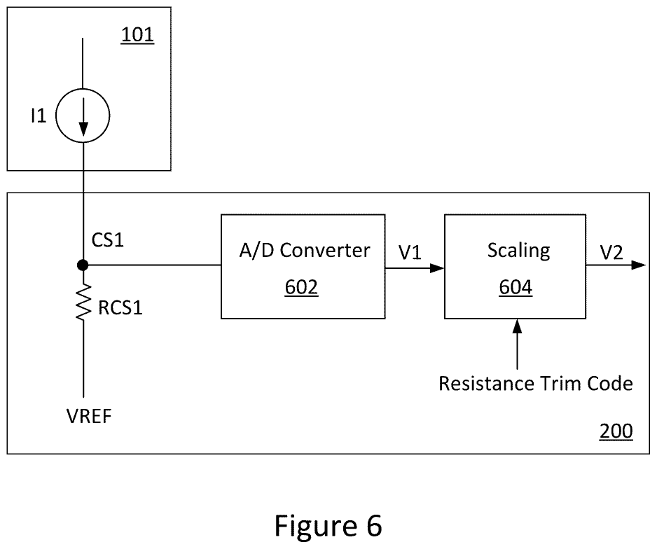

FIG. 6 illustrates a schematic diagram of a third implementation of the current sense compensation circuit in accordance with various embodiments of the present disclosure. In the multiphase controller 200, the current sense signal CS1 is fed into an analog-to-digital (A/D) converter 602. The A/D converter 602 is configured to convert the voltage on the node CS1 into a digital signal V1. A scaling unit 604 is employed to generate a compensated current sense signal based on the output of the A/D converter 602 and a resistance trim code. As every part of the current sense circuit is trimmed, this information is collected as the resistance trim code. This resistance trim code is used to scale the raw data generated by the A/D converter 602.

As shown in FIG. 6, an input of the A/D converter 602 is connected to a common node of the first current source I1 and the first current sense resistor RCS1. The scaling unit 604 is configured to receive an output of the A/D converter 602 and the resistance trim code. Based on the received signals, the scaling unit 604 is configured to generate a compensated current sense signal. The output of the scaling unit 604 is used for current telemetry.

It should be noted that an exemplary embodiment described for the current telemetry in the first phase (CS1) in the multiphase system is equally applicable to the other phases, with each phase functioning in a similar manner unless otherwise specified.

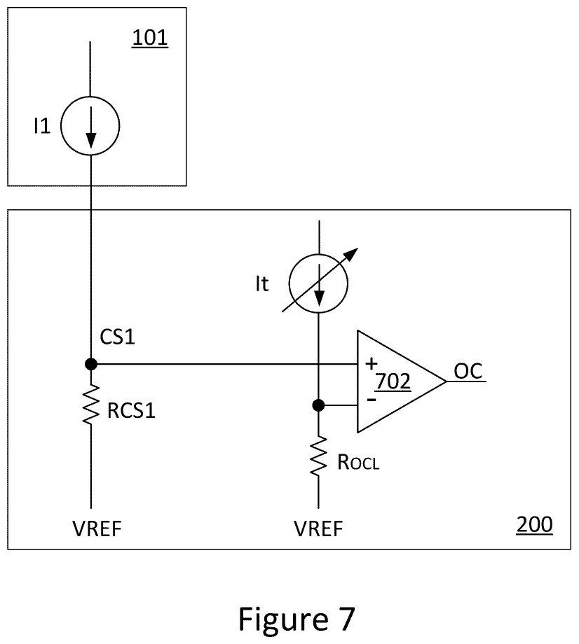

FIG. 7 illustrates a schematic diagram of a fourth implementation of the current sense compensation circuit in accordance with various embodiments of the present disclosure. In the multiphase controller 200, the current sense signal CS1 is fed into a non-inverting input of a comparator 702. The comparator 702 functions as an over current protection comparator. The output of the comparator 702 is employed to indicate an over current situation. As shown in FIG. 7, a non-inverting input of the comparator 702 is connected to a common node of the first current source I1 and the first current sense resistor RCS1. The adjustable current source It and the current limit resistor R_{OCL} are connected in series. A common node of the adjustable current source It and the current limit resistor R_{OCL} is connected to an inverting input of the comparator 702. The current limit resistor R_{OCL} is configured to generate a current limit threshold. In operation, a current flowing through the adjustable current source is dynamically adjusted so as to achieve accurate current protection across the varying operating conditions.

It should be noted that since RCS1 and ROCL are both implemented on the same semiconductor die, with their design and layout matched, they will track in the same direction, whether increasing or decreasing. As a result, overcurrent limit accuracy is maintained, even when using an uncompensated current sense signal for over current protection. The current flowing through the adjustable current source is employed to further improve the accuracy of over current protection.

It should be noted that an exemplary embodiment described for the over current protection in the first phase (CS1) in the multiphase system is equally applicable to the other phases, with each phase functioning in a similar manner unless otherwise specified.

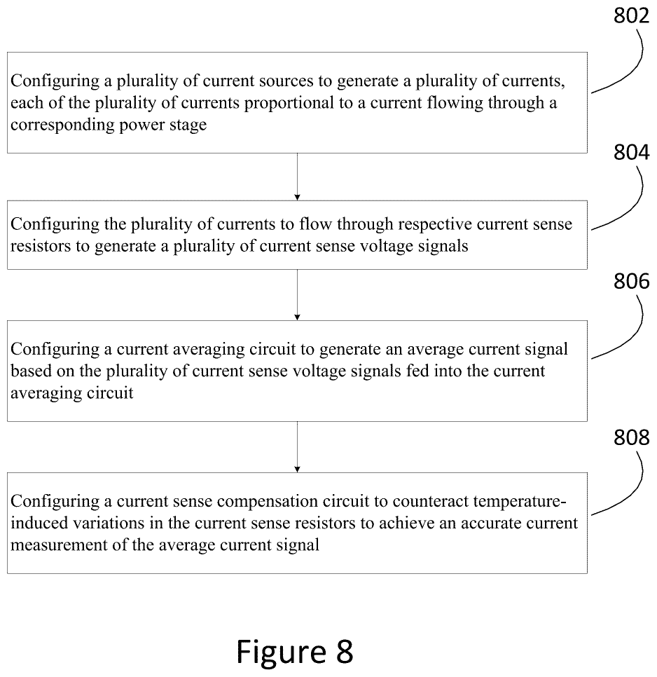

FIG. 8 illustrates a flow chart of a method for accurate current sensing in the power conversion system shown in FIG. 1 in accordance with various embodiments of the present disclosure. This flowchart shown in FIG. 8 is merely an example, which should not unduly limit the scope of the claims. One of ordinary skill in the art would recognize many variations, alternatives, and modifications. For example, various steps illustrated in FIG. 8 may be added, removed, replaced, rearranged and repeated.

At step 802, a plurality of current sources is configured to generate a plurality of currents, each of the plurality of currents proportional to a current flowing through a corresponding power stage.

At step 804, the plurality of currents is configured to flow through respective current sense resistors to generate a plurality of current sense voltage signals.

At step 806, a current averaging circuit is configured to generate an average current signal based on the plurality of current sense voltage signals fed into the current averaging circuit.

At step 808, a current sense compensation circuit is configured to counteract temperature-induced variations in the current sense resistors to achieve an accurate current measurement of the average current signal.

The method further comprises configuring a first current source of the plurality of current sources to generate a first current proportional to a current flowing through a first power stage, configuring the first current to flow through a first current sense resistor to generate a first current sense voltage signal of the plurality of current sense voltage signals, configuring a second current source of the plurality of current sources to generate a second current proportional to a current flowing through a second power stage, configuring the second current to flow through a second current sense resistor to generate a second current sense voltage signal of the plurality of current sense voltage signals, configuring a current averaging circuit to generate the average current signal based on the first current sense voltage signal and the second current sense voltage signal, and configuring the current sense compensation circuit to counteract temperature-induced variations in the first current sense resistor and the second current sense resistor to achieve an accurate current measurement of the average current signal.

In some embodiments, the current averaging circuit comprises an amplifier having a non-inverting input, an inverting input and an output, and wherein the non-inverting input of the amplifier is connected to a common node of the first current source and the first current sense resistor through a first resistor, the non-inverting input of the amplifier is connected to a common node of the second current source and the second current sense resistor through a second resistor, and the output of the amplifier is connected to the inverting input of the amplifier, and the current sense compensation circuit comprises a first current sense compensation amplifier, a second current sense compensation amplifier, a first current sense compensation resistor, a second current sense compensation resistor, a third current sense compensation resistor and a fourth current sense compensation resistor, and wherein an inverting input of the first current sense compensation amplifier is connected to the output of the amplifier through the first current sense compensation resistor, a non-inverting input of the first current sense compensation amplifier is connected to a predetermined reference, the second current sense compensation resistor is connected between the inverting input and an output of the first current sense compensation amplifier, an inverting input of the second current sense compensation amplifier is connected to the output of the first current sense compensation amplifier through the third current sense compensation resistor, a non-inverting input of the second current sense compensation amplifier is connected to the predetermined reference, and the fourth current sense compensation resistor is connected between the inverting input and an output of the second current sense compensation amplifier.

The method further comprises configuring an analog-to-digital converter to convert the first current sense voltage signal into a first current sense digital signal, and based on a resistance trim code, scaling the first current sense digital signal to generate a compensated current sense signal.

The method further comprises configuring a comparator to compare the first current sense voltage signal with a current limit reference, wherein the current limit reference is tapped at a common node of an adjustable current source and a current limit resistor, and dynamically adjusting the adjustable current source to adjust the current limit reference.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. An apparatus comprising:
a plurality of current sense resistors formed on a semiconductor die, wherein one current sense resistor of the plurality of current sense resistors is configured to receive a current signal proportional to a current flowing through a power stage; and
a current sense compensation circuit configured to counteract temperature-induced variations in the plurality of current sense resistors to achieve accurate current measurements across varying operating conditions.

2. The apparatus of claim 1, wherein:
a first current sense resistor of the plurality of current sense resistors is connected between a first current source and a reference voltage, wherein the first current source is configured to produce a first current signal proportional to a current flowing through a first power stage; and
a second current sense resistor of the plurality of current sense resistors is connected between a second current source and the reference voltage, wherein the second current source is configured to produce a second current signal proportional to a current flowing through a second power stage.

3. The apparatus of claim 2, wherein:
the first power stage and a first inductor are connected in series to form a first step-down power conversion stage; and
the second power stage and a second inductor are connected in series to form a second step-down power conversion stage, and wherein the first step-down power conversion stage and the second step-down power conversion stage are connected in parallel between an input voltage bus and an output voltage bus.

4. The apparatus of claim 2, further comprising:
an amplifier having a non-inverting input, an inverting input and an output, wherein:
the non-inverting input of the amplifier is connected to a common node of the first current source and the first current sense resistor through a first resistor;
the non-inverting input of the amplifier is connected to a common node of the second current source and the second current sense resistor through a second resistor; and
the output of the amplifier is connected to the inverting input of the amplifier, and wherein the output of the amplifier is configured to generate a voltage signal equal to a sum of the voltage reference and an average current signal.

5. The apparatus of claim 4, wherein:
the current sense compensation circuit comprises a first current sense compensation amplifier, a second current sense compensation amplifier, a first current sense compensation resistor, a second current sense compensation resistor, a third current sense compensation resistor and a fourth current sense compensation resistor, and wherein:
an inverting input of the first current sense compensation amplifier is connected to the output of the amplifier through the first current sense compensation resistor;
a non-inverting input of the first current sense compensation amplifier is connected to a predetermined reference;
the second current sense compensation resistor is connected between the inverting input and an output of the first current sense compensation amplifier;
an inverting input of the second current sense compensation amplifier is connected to the output of the first current sense compensation amplifier through the third current sense compensation resistor;
a non-inverting input of the second current sense compensation amplifier is connected to the predetermined reference; and
the fourth current sense compensation resistor is connected between the inverting input and an output of the second current sense compensation amplifier.

6. The apparatus of claim 5, wherein:
the fourth current sense compensation resistor is an adjustable resistor, and wherein a resistance of the fourth current sense compensation resistor is dynamically adjusted so as to achieve the accurate current measurements across the varying operating conditions.

7. The apparatus of claim 2, further comprising:
an amplifier having a non-inverting input, an inverting input and an output, wherein:
the non-inverting input of the amplifier is connected to a common node of the first current source and the first current sense resistor through a first resistor;
the non-inverting input of the amplifier is connected to a common node of the second current source and the second current sense resistor through a second resistor; and
the output of the amplifier is connected to the inverting input of the amplifier through the current sense compensation circuit.

8. The apparatus of claim 7, wherein:
the current sense compensation circuit comprises a current sense compensation amplifier, a first current sense compensation resistor, a second current sense compensation resistor, a third current sense compensation resistor and a fourth current sense compensation resistor, and wherein:
the first current sense compensation resistor and the second current sense compensation resistor are connected in series between the output of the amplifier and a predetermined reference, and wherein a common node of the first current sense compensation resistor and the second current sense compensation resistor is connected to the inverting input of the amplifier;
the third current sense compensation resistor and the fourth current sense compensation resistor are connected in series between the output of the amplifier and the predetermined reference, and wherein a common node of the third current sense compensation resistor and the fourth current sense compensation resistor is connected to a non-inverting input of the current sense compensation amplifier; and
an output of the current sense compensation amplifier is connected to an inverting input of the current sense compensation amplifier.

9. The apparatus of claim 8, wherein:
the fourth current sense compensation resistor is an adjustable resistor, and wherein a resistance of the fourth current sense compensation resistor is dynamically adjusted so as to achieve the accurate current measurements across the varying operating conditions.

10. The apparatus of claim 2, further comprising:
an analog-to-digital converter, wherein:
an input of the analog-to-digital converter is connected to a common node of the first current source and the first current sense resistor; and
a scaling unit configured to receive an output of the analog-to-digital converter and a resistance trim code, and generate a compensated current sense signal based on the output of the analog-to-digital converter and the resistance trim code.

11. The apparatus of claim 2, further comprising:
a comparator, a current limit resistor and an adjustable current source, wherein:
an non-inverting input of the comparator is connected to a common node of the first current source and the first current sense resistor;
the adjustable current source and the current limit resistor are connected in series; and
a common node of the adjustable current source and the current limit resistor is connected to an inverting input of the comparator.

12. The apparatus of claim 11, wherein:
a current flowing through the adjustable current source is dynamically adjusted so as to achieve the accurate current measurements across the varying operating conditions.

13. A method comprising:
configuring a plurality of current sources to generate a plurality of currents, each of the plurality of currents proportional to a current flowing through a corresponding power stage;
configuring the plurality of currents to flow through respective current sense resistors to generate a plurality of current sense voltage signals;
configuring a current averaging circuit to generate an average current signal based on the plurality of current sense voltage signals fed into the current averaging circuit; and
configuring a current sense compensation circuit to counteract temperature-induced variations in the current sense resistors to achieve an accurate current measurement of the average current signal.

14. The method of claim 13, further comprising:
configuring a first current source of the plurality of current sources to generate a first current proportional to a current flowing through a first power stage;
configuring the first current to flow through a first current sense resistor to generate a first current sense voltage signal of the plurality of current sense voltage signals;
configuring a second current source of the plurality of current sources to generate a second current proportional to a current flowing through a second power stage;
configuring the second current to flow through a second current sense resistor to generate a second current sense voltage signal of the plurality of current sense voltage signals;
configuring a current averaging circuit to generate the average current signal based on the first current sense voltage signal and the second current sense voltage signal; and
configuring the current sense compensation circuit to counteract temperature-induced variations in the first current sense resistor and the second current sense resistor to achieve an accurate current measurement of the average current signal.

15. The method of claim 14, wherein:
the current averaging circuit comprises an amplifier having a non-inverting input, an inverting input and an output, and wherein:
the non-inverting input of the amplifier is connected to a common node of the first current source and the first current sense resistor through a first resistor;
the non-inverting input of the amplifier is connected to a common node of the second current source and the second current sense resistor through a second resistor; and
the output of the amplifier is connected to the inverting input of the amplifier; and
the current sense compensation circuit comprises a first current sense compensation amplifier, a second current sense compensation amplifier, a first current sense compensation resistor, a second current sense compensation resistor, a third current sense compensation resistor and a fourth current sense compensation resistor, and wherein:
an inverting input of the first current sense compensation amplifier is connected to the output of the amplifier through the first current sense compensation resistor;
a non-inverting input of the first current sense compensation amplifier is connected to a predetermined reference;
the second current sense compensation resistor is connected between the inverting input and an output of the first current sense compensation amplifier;
an inverting input of the second current sense compensation amplifier is connected to the output of the first current sense compensation amplifier through the third current sense compensation resistor;
a non-inverting input of the second current sense compensation amplifier is connected to the predetermined reference; and
the fourth current sense compensation resistor is connected between the inverting input and an output of the second current sense compensation amplifier.

16. The method of claim 14, further comprising:
configuring an analog-to-digital converter to convert the first current sense voltage signal into a first current sense digital signal; and
based on a resistance trim code, scaling the first current sense digital signal to generate a compensated current sense signal.

17. The method of claim 14, further comprising:
configuring a comparator to compare the first current sense voltage signal with a current limit reference, wherein the current limit reference is tapped at a common node of an adjustable current source and a current limit resistor; and
dynamically adjusting the adjustable current source to adjust the current limit reference.

18. A power conversion system comprising:
a plurality of power stages connected in parallel between an input voltage bus and an output voltage bus; and
a controller comprising a plurality of current sense resistors and a current sense compensation circuit, wherein:
one current sense resistor of the plurality of current sense resistors is configured to receive a current signal proportional to a current flowing through a power stage; and
a current sense compensation circuit is configured to counteract temperature-induced variations in the plurality of current sense resistors to achieve accurate current measurements across varying operating conditions.

19. The power conversion system of claim 18, further comprising:
a current averaging circuit comprising an amplifier having a non-inverting input, an inverting input and an output, wherein:
the non-inverting input of the amplifier is connected to a common node of the first current source and the first current sense resistor through a first resistor;
the non-inverting input of the amplifier is connected to a common node of the second current source and the second current sense resistor through a second resistor; and
the output of the amplifier is connected to the inverting input of the amplifier, and wherein the current sense compensation circuit comprises a first current sense compensation amplifier, a second current sense compensation amplifier, a first current sense compensation resistor, a second current sense compensation resistor, a third current sense compensation resistor and a fourth current sense compensation resistor, and wherein:
an inverting input of the first current sense compensation amplifier is connected to the output of the amplifier through the first current sense compensation resistor;
a non-inverting input of the first current sense compensation amplifier is connected to a predetermined reference;
the second current sense compensation resistor is connected between the inverting input and an output of the first current sense compensation amplifier;
an inverting input of the second current sense compensation amplifier is connected to the output of the first current sense compensation amplifier through the third current sense compensation resistor;
a non-inverting input of the second current sense compensation amplifier is connected to the predetermined reference; and
the fourth current sense compensation resistor is connected between the inverting input and an output of the second current sense compensation amplifier.

20. The power conversion system of claim 19, wherein:
each of plurality of power conversion stages is a smart power stage formed by a high-side switch, a low-side switch and a driver.
